(19) United States
(12) Patent Application Publication
(10) Pub. No.: US 2017/0003355 A1
(43) Pub. Date: Jan. 5, 2017

(54) METHOD AND DEVICE FOR DETERMINING THE IMPEDANCE OF AN ENERGY STORAGE ELEMENT OF A BATTERY

(71) Applicant: COMMISSARIAT A L'ENERGIE ATOMIQUE ET AUX ENERGIES ALTERNATIVES, Paris (FR)

(72) Inventors: Marco RANIERI, Gieres (FR); Vincent HEIRIES, Saint Jean De Moirans (FR)

(21) Appl. No.: 15/113,101

(22) PCT Filed: Jan. 12, 2015
(86) PCT No.: PCT/EP2015/050436

§ 371 Date: Jul. 21, 2016

(30) Foreign Application Priority Data
Jan. 22, 2014 (FR) 1450508

(51) Int. Cl. G01R 31/36

(52) U.S. Cl. CPC G01R 31/3662; G01R 31/3679

(57) ABSTRACT

A method for determining the impedance of an energy storage element of an electric battery comprises the steps of: applying a predetermined sequence of current variations to the element; measuring the voltage variations at the terminal of the element in response to the application of said sequence; and determining the impedance of the element from the measured voltage variations, wherein said is a non-binary sequence produced by the convolution of a pseudo-random binary sequence with finite impulse response filter coefficients.

### BACKGROUND

The present disclosure generally relates to the field of electric batteries, and more particularly to a method and a device for determining the impedance of an energy storage element of a battery.

### DISCUSSION OF THE RELATED ART

An electric battery is a group of a plurality of re-chargeable elementary cells (cells, accumulators, etc.) connected in series and/or in parallel between two voltage supply nodes or terminals.

In certain applications, the impedance of an energy storage element of the battery such as an elementary cell of the battery, a module of a plurality of elementary cells connected in series and/or in parallel between two nodes of the battery, or the actual battery, is desired to be known. Knowing the impedance of the element at certain frequencies may in particular enable to determine information relative to the state of the element, such as its state of charge, also called SOC, its state of health, also called SOH, its state of energy, also called SOE, a degradation (increase) of its internal resistance, a degradation (decrease) of its capacitance, etc. As an example, knowing the impedance of an energy storage element of a battery in lithium-ion technology in a low frequency band, typically lower than 5 Hz, may enable to determine the SOC of the element, and knowing the impedance of the element in a higher frequency band, typically between 10 and 100 Hz, may enable to determine the SOH of the element.

Existing methods and devices for measuring the impedance of an energy storage element of a battery have various disadvantages that it would be desirable to at least partly overcome.

### SUMMARY

Thus, an embodiment provides a method of determining the impedance of an energy storage element of an electric battery, comprising the steps of: applying to the element a predetermined sequence of current variations; measuring the voltage variations across the element as a response to the application of the sequence; and determining the impedance of the element based on the measured voltage variations, wherein the sequence is a non-binary sequence obtained by convolution of a pseudo-random binary sequence with coefficients of a finite impulse response filter.

According to an embodiment of the present invention, the filter is selected so that the frequency spectrum of the sequence has a pass-band with a width in the range from 1 Hz to 50 kHz having an approximately constant level, that is, varying by less than 10 dB, and has an attenuation lower than −30 dB outside of this pass-band.

According to an embodiment of the present invention, the filter is a root raised cosine filter.

According to an embodiment of the present invention, the filter is a raised cosine filter.

According to an embodiment of the present invention, the non-binary sequence is modulated on a periodic carrier signal before being applied to the element.

According to an embodiment of the present invention, the periodic signal is sinusoidal.

Another embodiment provides a device for determining the impedance of an energy storage element of an electric battery, comprising a circuit capable of: applying to the element a predetermined sequence of current variations; measuring the voltage variations across the element as a response to the application of the sequence; and determining the impedance of the element based on the measured voltage variations, wherein the sequence is a non-binary sequence obtained by convolution of a pseudo-random binary sequence with coefficients of a finite impulse response filter.

According to an embodiment of the present invention, the circuit comprises a discharge branch intended to be connected in parallel with the element, this branch comprising a transistor capable of being controlled in an area of linear operation to apply to the element non-binary current variations.

According to an embodiment of the present invention, the transistor is controlled via an operational amplifier, and a feedback loop connects the branch to an input terminal of the amplifier.

According to an embodiment of the present invention, the circuit comprises a power supply circuit capable of storing electric energy in a capacitor before an impedance measurement phase, to power the device during the measurement phase.

Another embodiment provides an assembly comprising: an electric battery comprising at least one energy storage element; and a device for managing the battery coupled to the battery, the management device comprising at least one device of the above-mentioned type, capable of measuring the impedance of the storage element.

According to an embodiment of the present invention, the battery comprises a plurality of storage elements, and the management device comprises a plurality of impedance measurement devices respectively assigned to the different storage elements, the different impedance measurement devices being capable of applying different current variation sequences to the different storage elements.

According to an embodiment of the present invention, the management device is capable of identifying the different elements with the current variation sequence which is applied thereto during an impedance measurement.

### BRIEF DESCRIPTION OF THE DRAWINGS

The foregoing and other features and advantages will be discussed in detail in the following non-limiting description of specific embodiments in connection with the accompanying drawings, among which:

FIG. 1 schematically and partially illustrates an example of a device for measuring the impedance of an energy storage element of a battery;

FIG. 2 is a diagram showing an example of a current variation control sequence which may be applied to an energy storage element of a battery to measure the impedance thereof;

FIG. 3 is a diagram showing the frequency spectrum of a current variation sequence of the type shown in FIG. 2;

FIG. 4 is a diagram showing coefficients of an example of a finite impulse response filter;

FIG. 5 is a diagram showing an example of a current variation control sequence which may be applied to an energy storage element to measure its impedance according to an embodiment;

FIG. 6 is a diagram showing the frequency spectrum of a current variation sequence of the type shown in FIG. 5;

FIG. 7 is a diagram showing the frequency spectrum of a current variation sequence which may be applied to an energy storage element to measure its impedance according to an alternative embodiment;

FIG. 8 is an electric diagram illustrating an embodiment of a device for measuring the impedance of an energy storage element of a battery;

FIG. 9 is an electric diagram illustrating a first alternative embodiment of the impedance measurement device of FIG. 8;

FIG. 10 is an electric diagram illustrating a second alternative embodiment of the impedance measurement device of FIG. 8; and

FIG. 11 is an electric diagram illustrating a third alternative embodiment of the impedance measurement device of FIG. 8.

### DETAILED DESCRIPTION

For clarity, the same elements have been designated with the same reference numerals in the various drawings and, further, the various drawings are not to scale. Further, only those elements which are useful to the understanding of the described embodiments have been detailed. In particular, the uses which may be made of the impedance measurements performed by means of the provided methods and devices have not been detailed, the described embodiments being compatible with all known uses of measurements of the impedance of battery energy storage elements.

Impedance measurement methods and devices capable of being implemented by or integrated in an embarked battery management system, also called BMS, that is, an electronic system permanently coupled to the battery, capable of implementing various functions such as battery protection functions during charge or discharge phases, battery cell balancing functions, functions of monitoring the state of charge and/or the state of aging of the battery, etc., are here more particularly considered. The described embodiments are however not limited to this specific case. As a variation, the impedance measurement methods and devices described in the present application may be implemented by or integrated in non-embarked lightweight diagnosis tools, intended to be connected to the battery only during battery maintenance phases, for example, tools intended for mechanics in the case of batteries for electric vehicles.

To measure the impedance of an energy storage element of a battery at a frequency f, it may be provided to submit the element to a sinusoidal current variation of frequency f. The voltage variation across the element as a response to the current variation is then measured, and the impedance of the element at frequency f is determined from the measured voltage variation. To measure the impedance of the element at a plurality of frequencies, the operation may be repeated at the various frequencies of interest. Impedance measurements of this type, called spectrum scan measurements, may for example be performed in a laboratory when the battery is off and possibly dismounted. A disadvantage of spectrum scan measurements is that they are relatively long, which may be a problem for an implementation in an embarked BMS-type management system, or in a lightweight diagnosis tool intended to provide a fast impedance measurement over a relative wide frequency range. It should further be noted that existing BMSs are not capable of applying a sinusoidal current variation to an energy storage element of a battery, but may only apply binary sequences of current variations switching relatively abruptly fashion between two states.

As a variation, to measure the impedance of an energy storage element of a battery simultaneously at a plurality of frequencies, another solution is to submit the element to a wideband current variation, that is, a variation having its frequency spectrum containing a plurality of frequencies of interest. The voltage variation across the element as a response to a wideband current variation is then measured and analyzed to determine the impedance of the element at the various frequencies of the current excitation signal. This allows a faster measurement than with a spectrum scan method of the above-mentioned type. However, to implement a wideband impedance measurement in a BMS or in a lightweight diagnosis tool, a difficulty is the generation of an excitation signal having a frequency spectrum well adapted to the measurement which is desired to be performed.

An example of an embarked BMS-type battery management system, including a device for measuring the impedance of battery cells, has been described in French patent application No. FR1353656 filed by the applicant on Apr. 24, 2013, which is incorporated herein by reference.

FIG. 1 schematically and partially illustrates an example of an impedance measurement device of the type described in above-mentioned application FR1353656. More particularly, FIG. 1 is an electric diagram showing an electric energy storage element 100 of a battery, and a circuit 110 connected across the storage element, circuit 110 being capable of applying to element 100 a binary sequence of current variations to measure the impedance thereof. In this example, circuit 110 comprises a branch comprising, in series, a power transistor 112 and a discharge resistor 114, this branch being connected in parallel across element 100. Circuit 110 further comprises a control circuit 116, for example, a microcontroller, connected to a control node of transistor 112 and capable of turning on or off transistor 112 (to branch or not a current of element 110) according to a predefined binary control sequence. As an example, control circuit 116 may be powered by element 100 itself, or by a secondary power source.

To measure the impedance of element 100, control circuit 116 applies to transistor 112 the predefined binary control sequence at a rate (number of samples per second) fs selected according to the frequency for which the impedance is desired to be measured. In the following description, the rate of application of a digital control sequence (binary or not) may also be designated by expression “sequence frequency”. Element 100 is thus submitted to a corresponding binary current variation sequence. The voltage variation across element 100 as a response to this current variation is measured, and an impedance value of element 100 is determined from the measured voltage variation. To measure the impedance of element 110 at a plurality of different frequencies of interest, the operation may be repeated by modifying rate fs of application of the binary control sequence. It should be noted that the measurement of the voltage variation across element 100 as a response to the current excitation applied via transistor 112 may be performed “locally”, that is, directly across element 100, or “remotely” from the main terminals of the battery. The impedance measurement may be performed during the normal operation of the battery, without requiring turning off or dismounting the battery. In above-mentioned application FR1353656, it is provided to use a pseudo-random binary sequence to excite element 100 with a current during an impedance measurement. More particularly, it is provided to assign to each energy storage element of the battery a specific binary pseudo-random sequence, and when an impedance measurement of an element has to be performed, to excite the element with a current according to the specific binary pseudo-random sequence of this element. An advantage is that this enables, when the voltage variation of the element is “remotely” measured from the main terminals of the battery, to identify the excited element from the measured voltage variation sequence.

When a binary current variation sequence is applied to the element having its impedance desired to be measured, as occurs in above-mentioned application FR1353656, the frequency spectrum of the current variation contains a large number of frequencies, which might lead to believe that a wideband impedance measurement can be performed.

In practice, the inventors have however determined that to perform an accurate wideband impedance measurement, the frequency spectrum of the excitation signal should be as flat as possible in the band of interest. This enables the excitation signal to excite the element with substantially the same power at each frequency of the band of interest, and accordingly the signal-to-noise ratio of the impedance measurement is substantially the same at all the frequencies of the band of interest. Further, to minimize the power consumption associated with the impedance measurement, the frequency spectrum of the excitation signal should be close to zero outside of the band of interest, to avoid uselessly involving unwanted frequencies.

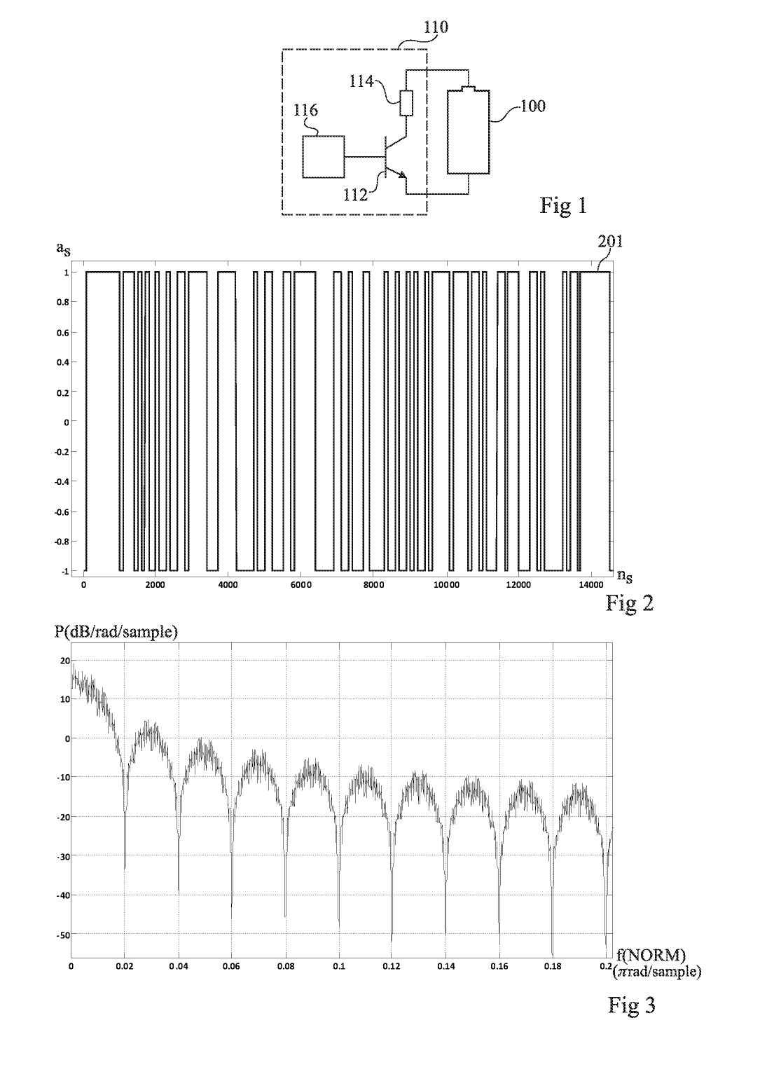

As illustrated in FIGS. 2 and 3 detailed hereafter, when a binary sequence (ON/OFF) of current variations is applied, the spectrum of this excitation signal is a spectrum with an infinite frequency support having a main lobe and, on either side of this lobe, lobes of decreasing amplitude. This type of spectrum is not adapted to the forming of an accurate wideband impedance measurement of low power consumption.

FIG. 2 is a diagram showing an example of a pseudo-random binary control sequence 201 capable of being applied to the control node of transistor 112 of FIG. 1, to submit element 100 to a current variation sequence of same shape to measure its impedance. In FIG. 2, the axis of abscissas shows number ns of the samples of the sequence, and the axis of ordinates shows value as of the samples. In FIG. 2, an amplitude as equal to 1 has been assigned to the high state of the binary sequence, corresponding to an on state of transistor 112, and an amplitude as equal to −1 has been assigned to the low state of the binary sequence, corresponding to an off state of transistor 112. These values are however purely arbitrary and do not necessarily correspond to real values of signals to be applied to the gate of transistor 112. Further, in the drawing, a large number of samples has been shown (approximately 15,000). In practice, the pseudo-random binary sequence applied to perform an impedance measurement may have a different number of samples. Further, although this does not appear in FIG. 2, in the meaning of the present application, a pseudo-random binary sequence comprising N samples (N being an integer greater than 1) may either really comprise a pseudo-random sequence of N 1-bit samples, or be obtained by repetition (concatenation) of a pseudo-random pattern comprising a number of 1-bit samples smaller than N, for example, a pseudo-random pattern comprising a number of 1-bit samples in the range from 32 to 256.

FIG. 3 is a diagram showing the frequency spectrum of a pseudo-random binary sequence of current variations of the type shown in FIG. 2. In FIG. 3, the axis of abscissas shows frequency f(NORM), normalized with respect to a sampling frequency fe of the device of application of the binary sequence, expressed in π radians per sample (π rad/sample). Any value α in abscissa of FIG. 3 corresponds, in Hertz, to value (α*fe)/2. The axis of ordinates represents the power level, in decibel per radian per sample (dB/rad/sample), of the current excitation signal, at the different spectrum frequencies.

There clearly appears from FIG. 3 that the spectrum of a pseudo-random binary sequence does not have a shape enabling to perform an accurate wide band impedance measurement of low power consumption. One could at best make the assumption that the spectrum of FIG. 3 is sufficiently flat to perform a wideband impedance measurement in the first half of the first lobe, that is, between values 0 and 0.01 in normalized frequency. This range is however too limited to obtain in a single measurement the impedance of the energy storage element at all frequencies likely to be of interest. To scan the entire range of frequencies of interest, the measurement should thus be repeated a relatively large number of times, by varying frequency fs of the binary sequence. The power efficiency of each measurement is further relatively low since a large number of unused frequencies is excited each time the binary sequence is applied.

According to an aspect, it is here provided to perform a wideband impedance measurement by exciting the energy storage element by means of a predefined sequence of current variations, this sequence being non binary—that is, it has a number of variation levels greater than two—and being selected so that its frequency spectrum is approximately flat in the frequency band of interest, and as low as possible outside of this band. As a non-limiting example, the current variation sequence is selected so that its frequency spectrum has an approximately flat pass-band with a width in the range from 1 Hz to 50 kHz, a pass-band ripple smaller than 10 dB, a transition area between the pass-band and an attenuated band having a width in the range from 1 mHz to 1 kHz, and an attenuated band attenuation greater than 30 dB and preferably in the range from 50 to 80 dB.

To obtain a spectrum adapted to an accurate wideband measurement of high power efficiency, the inventors have deter-mined that the current variation sequence to be applied to the energy storage element may be obtained by convolution of any pseudo-random binary sequence, for example, of the type described in relation with FIG. 2, with the coefficients of a finite impulse response filter. As a non-limiting example, the pseudo-random binary sequence may be a Gold sequence or a Kasami sequence. As an example, the filter may be a root raised cosine filter or a raised cosine filter. The described embodiments are however not limited to these specific examples. More generally, it will be within the abilities of those skilled in the art to determine other types of finite impulse response filters capable of obtaining the desired spectrum shape, the selected filter being preferably a linear-phase finite impulse response filter. To decrease the complexity of the filter, a symmetrical filter will be preferably be selected. It should be noted that if a plurality of different frequency bands of interest are desired to be analyzed, a plurality of filters (and thus a plurality of sets of coefficients) may be provided to generate a plurality of control sequences from a same pseudo-random binary sequence.

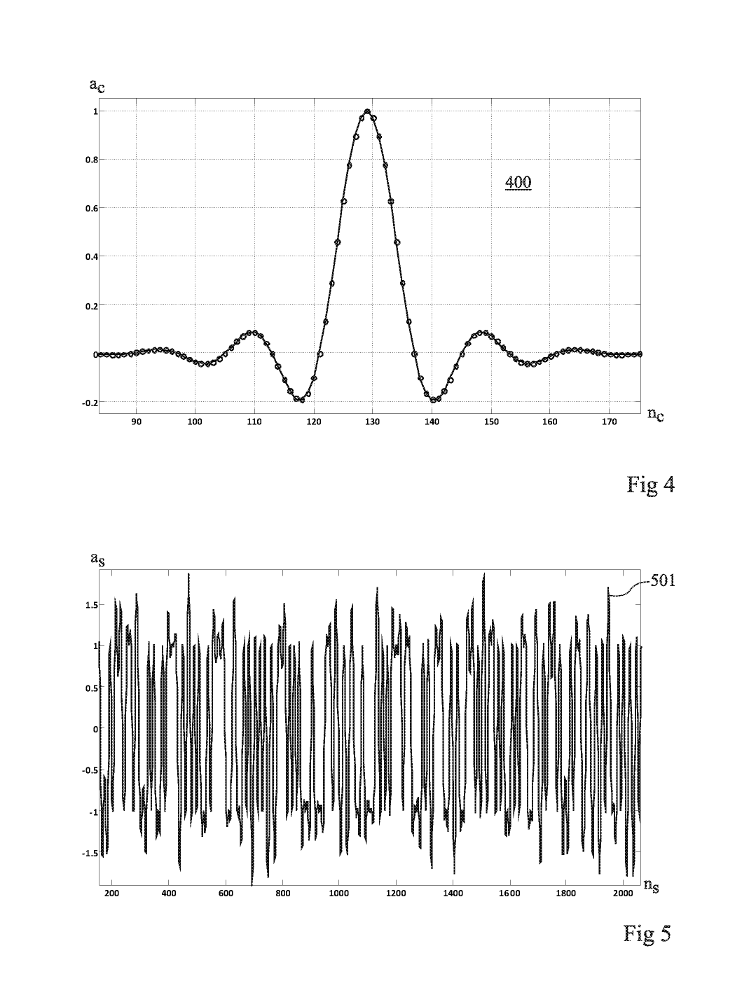

FIG. 4 is a diagram showing coefficients of an example of a root raised cosine finite impulse response filter 400 capable of being used to define, from a pseudo-random binary sequence, a current variation sequence to be applied to the energy storage element to measure the impedance thereof. In FIG. 4, the axis of abscissas shows number nc of the filter coefficients, and the axis of ordinates shows normalized value ac of the coefficients.

FIG. 5 is a diagram showing an example of a current variation control sequence 501 capable of being applied to an energy storage element of a battery to measure the impedance thereof. In FIG. 5, the axis of abscissas shows number ns of the samples of the sequence, and the axis of ordinates shows normalized value as of the samples. The samples of the sequence of FIG. 5 may be quantized over a number of bits greater than 1, for example, over a number of bits in the range from 4 to 64 bits. The sequence of the example of FIG. 5 corresponds to the convolution of a pseudo-random binary sequence of the type described in relation with FIG. 2 with the coefficients of a finite impulse response filter of the type shown in FIG. 4. As an example, frequency fs of the control sequence of FIG. 5 may be selected to be between 1 Hz and 1 kHz.

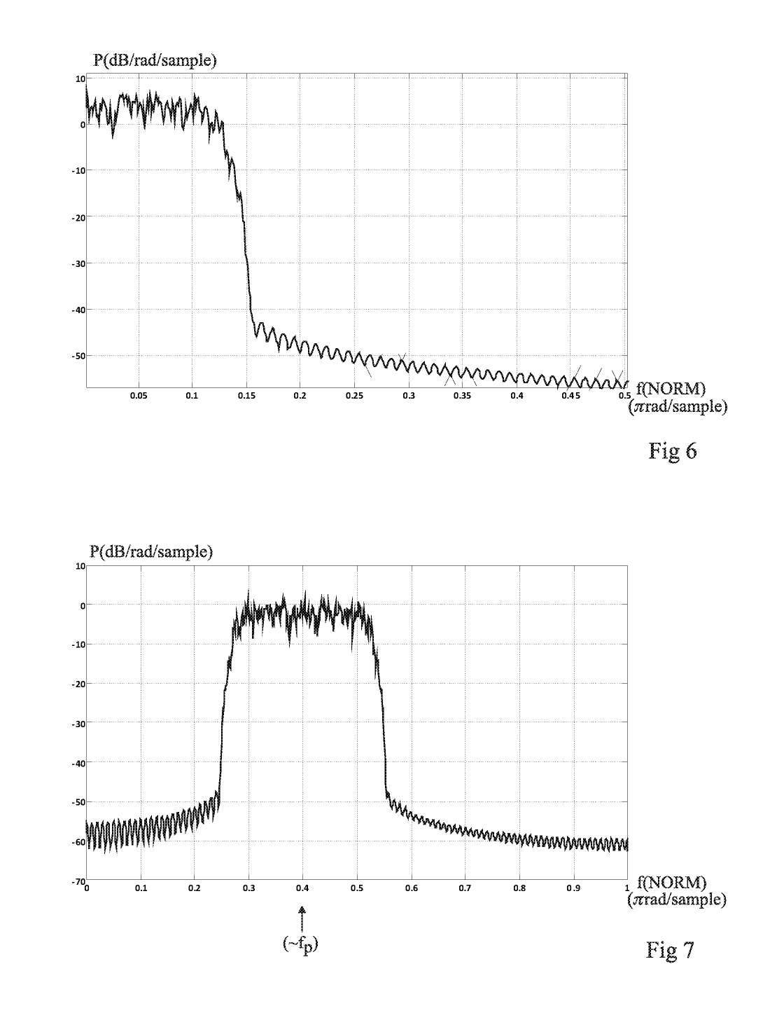

FIG. 6 is a diagram showing the frequency spectrum of the current variation control sequence shown in FIG. 5. In FIG. 6, the axis of abscissas shows frequency f(NORM), normalized with respect to a sampling frequency fe of the device of application of the binary sequence, and expressed in π radians per sample (π rad/sample). As in the example of FIG. 3, any value α in abscissa of FIG. 6 corresponds, in Hertz, to value (α*fe)/2. The axis of ordinates represents the power level, in decibel per radian per sample (dB/rad/sample), of the current excitation signal, at the different spectrum frequencies.

FIG. 6 clearly shows that the spectrum of the current variation control sequence of FIG. 5 is well adapted to an accurate wideband impedance measurement of high power efficiency. Indeed, the spectrum of FIG. 6 is approximately flat in the band between 0 and 0.12 π radians per sample, that is, between 0 and 0.06 fs in Hertz, and is strongly attenuated (lower than −30 dB) outside of this band. As a non-limiting example, if sampling frequency fs of the system is in the order of 16 kHz, a wideband impedance measurement may be performed in one go in a band in the range from 0 to 1,000 Hz. To adjust the shape of the spectrum and particularly the width of its pass-band, the shape of the finite impulse response filter may for example be adapted by adjusting a parameter of the filter current called roll-off factor in the art.

According to an alternative embodiment, the non-binary current variation sequence applied to the energy storage element may be modulated on a frequency carrier fp, to shift the frequency of the useful band of the excitation signal and to center it on frequency fₚ. This enables to perform a wideband impedance measurement at higher frequencies, for example, in the range from several tens of Hz to several tens of kHz (but only in a specific band). To perform this modulation, a non-binary current variation control sequence of the type described in relation with FIG. 5—obtained by convolution of a pseudo-random binary sequence with a finite impulse response filter—may for example be multiplied by a carrier signal of frequency fₚ, for example, signal sin(2π*fₚ*t).

Referring now to FIG. 7, is a diagram showing as an example the frequency spectrum of the current variation control sequence corresponding to the sequence of FIG. 5 modulated by a carrier frequency of frequency fp=0.2*fₛ (that is, 0.4 π radians per sample in normalized frequency). As a non-limiting example, sampling frequency fs may be in the order of 10 kHz, and frequency fₚ in the order of 2 kHz.

As appears in FIG. 7, the spectrum of the current variation sequence modulated at frequency fₚ is similar to that of FIG. 6, this time centered on frequency fₚ. More particularly, in the example of FIG. 7, the current variation spectrum is approximately flat in the band between fₚ —0.12 π radians per sample and fₚ+0.12 π radians per sample, that is, in Hz, between fₚ-0.06*fₛ and fₚ+0.06*fₛ.

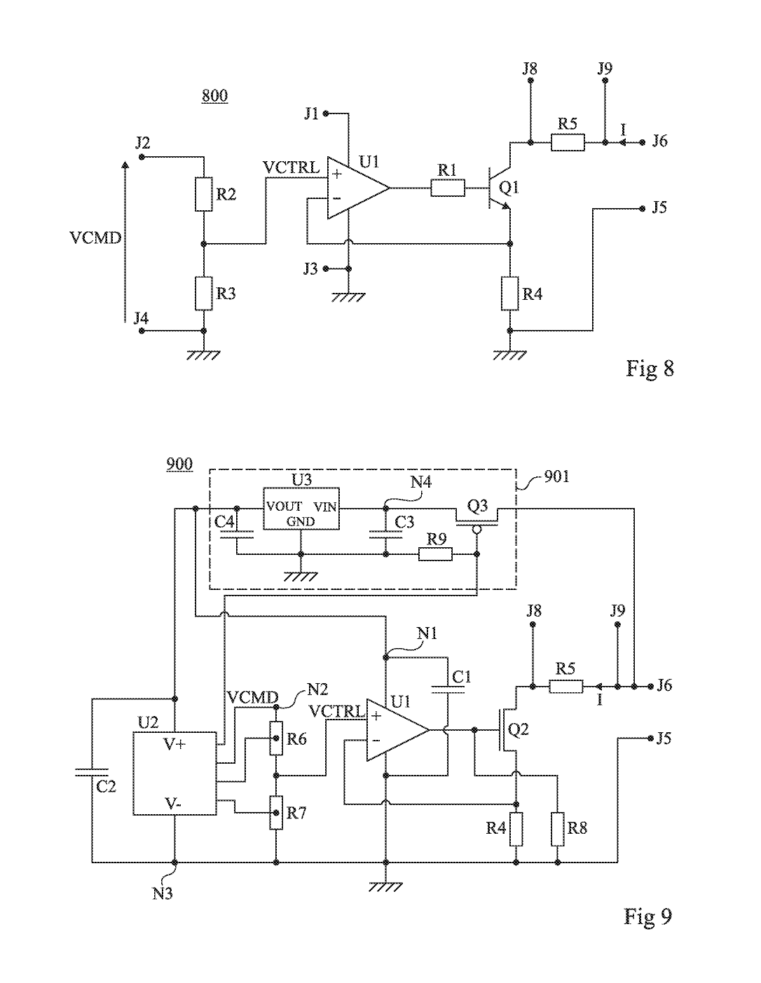

To be able to apply to an energy storage element a non-binary current variation sequence of the type described in relation with FIGS. 5 to 7, an impedance measurement device comprising a circuit for exciting the element to be tested with a current is provided, this circuit being capable of applying to the elements current variations having an amplitude capable of taking a number of levels greater than two. Embodiments of such circuits will be described hereafter in relation with FIGS. 8 and 9. The described embodiments are however not limited to these specific examples. More generally, any circuit capable of applying a non-binary current variation sequence to the storage element may be used. As an example, such a circuit may comprise a discharge branch connected in parallel across the element having its impedance desired to be measured, this branch comprising at least one transistor, for example, a MOS transistor or a bipolar transistor, this transistor being controlled by a control circuit in its linear operating area, so that the transistor can branch multiple current levels.

It should be noted that the provision of a current excitation circuit capable of applying non-binary current variations to the element being tested, for example, a circuit of the type described in relation with FIGS. 8 and 9, enables not only to perform wideband impedance measurements by exciting the element with signals of the type described in relation with FIGS. 5 to 7, but also to apply other types of non-binary excitation signals, for example, a sinusoidal signal enabling to measure the impedance of the element at an accurate specific frequency.

As indicated hereafter, the impedance measurement de-vices described in the present application may be either integrated to a BMS-type management system of the battery, or be part of an external diagnosis tool. In the case where the impedance measurement device is integrated in a BMS, a plurality of excitation circuits connected to different energy storage elements of the battery may be provided, for example, one excitation circuit per elementary cell of the battery. In this case, the different excitation circuits may either use the same current variation sequence to excite the elements to which they are connected during an impedance measurement, or use different current variation sequences. The use of different sequences may in particular enable, when the voltage variation resulting from a current excitation is remotely measured and not directly across the actual element, to identify the excited element via a management circuit where the excitation sequences assigned to the different elements are stored. The current excitation frequency or frequencies of the energy storage elements of the battery may for example be stored in the form of digital control values in a memory of the BMS.

FIG. 8 is an electric diagram illustrating an example of an embodiment of a device 800 for measuring the impedance of an energy storage element of a battery.

Device 800 of FIG. 8 comprises nodes J5 and J6 intended to be respectively connected to a negative terminal and to a positive terminal of the energy storage element (not shown in FIG. 8) having its impedance desired to be measured, for example, an elementary cell of the battery. Device 800 comprises a branch connected between nodes J6 and J5 (in parallel with the energy storage element) comprising, in series between nodes J6 and J5, a resistor R5, a transistor Q1, and a discharge resistor R4. In this example, transistor Q1 is an NPN-type bipolar transistor having its collector connected to resistor R5 and having its emitter connected to resistor R4. The described embodiments are however not limited to this specific case. As a variation, a PNP transistor or a MOS transistor may be used, provided to make possible adjustments which are within the abilities of those skilled in the art. Resistor R5 is a shunt resistor of small value, for example, smaller than 10 ohms, used to measure the current flowing through transistor Q1 via a voltage measurement device (not shown) connected across resistor R5 via measurement nodes J8 and J9. In the shown example, node J8 is connected to the collector of transistor Q1 and node J9 is connected to node J6.

Device 800 further comprises an operational amplifier U1 having a high power supply node J1 intended to receive a first power supply potential and having a low power supply node J3 intended to receive a second power supply potential lower than the first potential. The power supply of amplifier U1 may originate either from the actual element having its impedance desired to be measured, or from an external source, not shown. In the shown example, low power supply node J3 is connected to ground, which is here defined by the low potential of the element having its impedance desired to be measured, that is, by the potential of node J5. Amplifier U1 comprises an inverting input terminal (−) connected to the emitter of transistor Q1, and an output terminal connected to the base of transistor Q1 via a resistor R1.

Device 800 further comprises nodes J2 and J4 of application of a control voltage. In this example, node J4 is grounded. A resistor R2 and a resistor R3 are series-connected between nodes J2 and J4 to form a voltage-dividing bridge. The junction point of resistors R2 and R3 is connected to a non-inverting input terminal (+) of operational amplifier U1.

When a control voltage VCMD is applied between nodes J2 and J4, a proportional voltage VCTRL, determined by formula VCTRL=VCMD*(R3/(R2+R3)), is applied to the non-inverting input of amplifier U1. This voltage determines the current I supplied into transistor Q1 by the element being tested. This current is approximately equal to VCTRL/R4.

To apply a predetermined current variation sequence to the element being tested, it may be provided to apply an adapted voltage control sequence between nodes J2 and J4. The voltage control sequence may for example be stored in digital form in a memory, not shown, of device 800, and be applied to nodes J2 and J4 via a digital-to-analog converter (not shown).

As a variation, resistors R2 and/or R3 of device 800 may be replaced with potentiometers controlled in digital or analog fashion. To apply a predetermined sequence of current variations to the element being tested, one may then vary the values of resistors R2 and/or R3 according to an adapted control sequence.

The impedance of the element being tested may be determined from the voltage variation sequence measured between nodes J5 and J6 (or remotely from other nodes of the battery), and from the applied current variation which may optionally be measured via shunt resistor R5 for more accuracy (this especially enable to do away with a possible shift between the current variation orders applied by device 800 and the current variations effectively generated in the element being tested).

An advantage of device 800 is that the feedback loop connecting the emitter of transistor Q1 to the inverting input of amplifier U1 enables to apply an accurate current variation to the element being tested, independently from its state of charge and thus from the voltage thereacross.

FIG. 9 is an electric diagram illustrating another example of an embodiment of a device 900 for measuring the impedance of an energy storage element of a battery.

Device 900 of FIG. 9 comprises nodes J5 and J6 intended to be respectively connected to a negative terminal and to a positive terminal of the energy storage element (not shown in FIG. 9) having its impedance desired to be measured. Device 900 comprises a branch connected between nodes J6 and J5 (in parallel with the energy storage element) comprising, in series between nodes J6 and J5, a resistor R5, a transistor Q2, and a discharge resistor R4. Resistor R5 is a shunt resistor of small value, for example, smaller than 10 ohms, used to measure the current flowing through transistor Q2 via a voltage measurement device (not shown) connected across resistor R5 via measurement nodes J8 and J9. In this example, transistor Q2 is an N-channel MOS transistor having its source connected to resistor R5 and having its drain connected to resistor R4. Further, a resistor R8 connects the gate of transistor Q2 to node J5.

Device 900 further comprises an operational amplifier U1 having a high power supply terminal connected to a node N1 and having a low power supply terminal connected to node J5 (ground). In this example, the high power supply terminal of amplifier U1 (node N1) is connected to its low power supply terminal (node J5) by a capacitor C1. Amplifier U1 comprises an inverting input terminal (−) connected to the drain of transistor Q2, and an output terminal connected to the gate of transistor Q2.

Device 900 further comprises nodes N2 and N3 of application of a control voltage. In this example, node N3 is grounded. A resistor R6 and a resistor R7 are series-connected between nodes N2 and N3 to form a voltage-dividing bridge. The junction point of resistors R6 and R7 is connected to a non-inverting input terminal (+) of operational amplifier U1. In the shown example, resistors R6 and R7 are variable resistors (potentiometers).

Device 900 further comprises a control circuit U2, for example, a microcontroller, capable of applying a control voltage VCMD between nodes N2 and N3. In this example, control circuit U2 is further capable of controlling variable resistors R6 and R7. Control circuit U2 comprises a high power supply terminal connected to node N1 and a low power supply terminal connected to ground. In this example, the high power supply terminal of control circuit U2 (node N1) is connected to its low power supply terminal (node J5) by a capacitor C2.

When a control voltage VCMD is applied between nodes N2 and N3 by control circuit U2, a proportional voltage VCTRL, determined by formula VCTRL=VCMD*(R7/(R6+R7)), is applied to the non-inverting input of amplifier U1. This voltage determines the current I output into transistor Q2 by the element being tested. In this example, to apply a predetermined sequence of current variations to the element being tested, it may be provided to vary the values of resistors R6 and/or R7. As a variation, non-variable resistors R6 and R7 may be provided and the level of voltage VCMD may be varied.

Device 900 further comprises a power supply circuit 901 comprising a MOS transistor Q3, for example, a P-channel MOS transistor, connecting node J6 to a node N4, a capacitor C3 connecting node N4 to ground (node J5), a resistor R9 connecting the gate of transistor Q3 to ground, and a capacitor C4 connecting node N1 to ground. Circuit 901 further comprises a voltage regulator U3, for example, a LDO-type regulator, having an input VIN connected to node N4 and having an output VOUT connected to node N1, the regulator further comprising a ground terminal GND connected to node J5. The gate of transistor Q3 is connected to an input/output terminal of control circuit U2 of device 900.

An advantage of device 900 of FIG. 9 is that power supply circuit 901 may, before implementing an impedance measurement phase, store in capacitor C3 the energy necessary to power amplifier U1, control circuit U2, and, possibly potentiometers R6 and R7 (in the case of digitally-controlled potentiometers requiring a power supply) during an impedance measurement. Thus, during an impedance measurement, amplifier U1 and control circuit U2 (and possibly potentiometers R6 and R7) may be powered from capacitor C3 instead of being directly powered from the element being tested. This enables the impedance measurement not to be disturbed by the power consumption of the current excitation circuit.

As an example, transistor Q3 may be kept on (conductive) during a phase of charge of capacitor C3 prior to an impedance measurement phase. When an impedance measurement is implemented, control circuit U2 starts by turning off (blocking) transistor Q4. Components U1 and U2 are powered with the energy stored in capacitor C3. Regulator U3 provides on node N1 a voltage capable of powering components U1 and U2. No energy for powering device 900 is then sampled from the element being tested. Control circuit U2 then controls the application of the current variation sequence required for the impedance measurement. Once the measurement is over, control circuit U2 turns transistor Q3 back on to recharge capacitor C3 for a subsequent impedance measurement.

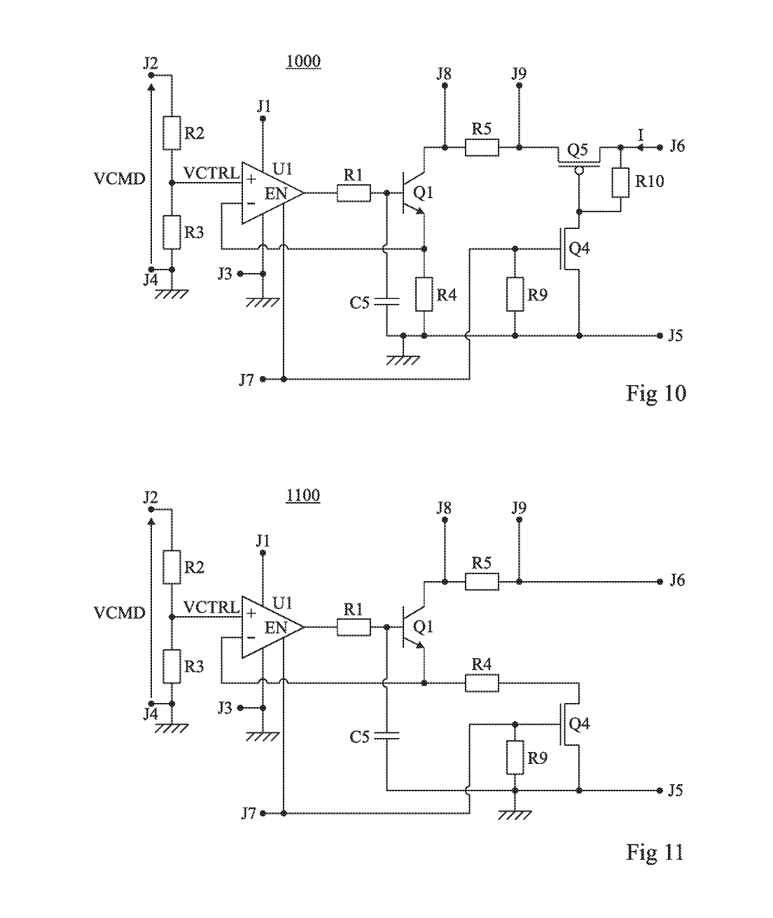

FIG. 10 is an electric diagram illustrating another example of an embodiment of a device 1000 for measuring the impedance of an energy storage element of a battery.

Device 1000 of FIG. 10 comprises the same elements as device 800 of FIG. 8, arranged substantially in the same way, and further comprises:

a capacitor C5 having a first electrode connected to the base of transistor Q1 and having a second electrode connected to node J5;

a P-channel MOS transistor Q5 connecting node J6 to resistor R5, that is, having its conduction nodes (source, drain) respectively connected to nodes J6 and J9;

a resistor R10 connecting the gate of transistor Q5 to node J6;

an N-channel MOS transistor Q4 connecting the gate of transistor Q5 to node J5; and

a resistor R9 connecting the gate of transistor Q4 to node J5.

Device 1000 of FIG. 10 further comprises a control node J7 connected on the one hand to the gate of transistor Q4 and on the other hand to a node EN of activation/deactivation of operational amplifier U1.

As in the example of FIG. 8, the battery element to be tested is connected between nodes J5 (negative terminal of the element) and J6 (positive terminal of the element).

Resistors R9 and R10 are preferably relatively high, for example, higher than 500 kΩ.

During an impedance measurement phase, device 1000 is made active. To achieve this, a binary signal applied to node J7 is set to the high state. Amplifier U1 is then active, and transistors Q4 and Q5 are in the on state. The operation of device 1000 is then similar to that of device 800 of FIG. 8.

Outside of impedance measurement phases, device 1000 is deactivated by the setting to the low state of the signal applied to node J7. Amplifier U1 is then inactive, and transistors Q4 and Q5 are in the non-conductive state (due to the pulling, respectively to the high state and to the low state, of the gates of transistors Q5 and Q4 by resistors R10 and R9).

An advantage of device 1000 of FIG. 10 is that it enables to avoid, outside of impedance measurement phases, a parasitic residual consumption of the energy stored in the battery element by the impedance measurement device (for example, due to leakage currents in transistor Q1 and/or to a non-zero offset voltage at the output of operational amplifier U1).

It should be noted that, in the example of FIG. 10, if a binary current variation sequence is desired to be applied to the battery element, as described in above-mentioned patent application FR1353656, it may be provided to set voltage VCTRL to a constant value, and to apply the binary sequence to node J7. This enables to increase the switching speed of transistor Q1, by doing away with the response time of amplifier U1 (which may be relatively long). In such an operating configuration, resistor R10 may however limit the switching speed of the device. To do away with such a limitation, it may be provided to decrease resistance R10. As a variation, to avoid to significant an impedance measurement error, the circuit of FIG. 10 may be modified as shown in FIG. 11.

Referring now to FIG. 11, is an electric diagram illustrating another example of an embodiment of a device 1100 for measuring the impedance of an energy storage element of a battery.

Device 1100 of FIG. 11 comprises the same elements as device 800 of FIG. 8, arranged substantially in the same way, except that resistor R4 is not directly connected to node J5, but is connected to node J5 via an N-channel MOS transistor Q4.

Device 1100 of FIG. 11 further comprises a capacitor C5 having a first electrode connected to the base of transistor Q1 and having a second electrode connected to node J5, and a resistor R9 connecting the gate of transistor Q4 to node J5.

Device 1100 of FIG. 11 further comprises a control node J7 connected on the one hand to the gate of transistor Q4 and on the other hand to a node EN of activation/deactivation of operational amplifier U1.

The operation of device 1100 of FIG. 11 is similar to that of device 1000 of FIG. 10. An advantage is that, when it is directly driven by node J7, transistor Q4 can switch faster than in the example of FIG. 10.

It should further be noted that in the examples of FIGS. 10 and 11, if the activation/deactivation response (via node EN) of amplifier U1 is not sufficiently fast to apply a binary current variation sequence, two separate nodes J7 and J7′ respectively connected to node EN and to the gate of transistor Q4 may be provided. To apply a binary current variation sequence, the signal on node J7 may then be kept in the high state and the binary sequence may be applied to node J7′.

1. A method of determining the impedance of an energy storage element of an electric battery, comprising the steps of:
applying to the element a predetermined sequence of current variations;
measuring the voltage variations across the element as a response to the application of said sequence; and
determining the impedance of the element based on the measured voltage variations,
wherein said sequence is a non-binary sequence obtained by convolution of a pseudo-random binary sequence with coefficients of a finite impulse response filter.

2. The method of claim 1, wherein the filter is selected so that the frequency spectrum of said sequence has a pass-band with a width in the range from 1 Hz to 50 kHz having an approximately constant level, that is, varying by less than 10 dB, and has an attenuation lower than −30 dB outside of this pass-band.

3. The method of claim 1, wherein the filter is a root raised cosine filter.

4. The method of claim 1, wherein the filter is a raised cosine filter.

5. The method of claim 1, wherein said non-binary sequence is modulated on a periodic carrier signal before being applied to the element.

6. The method of claim 5, wherein said periodic signal is sinusoidal.

7. A device for determining the impedance of an energy storage element of an electric battery, comprising a circuit capable of:
applying to the element a predetermined sequence of current variations;
measuring the voltage variations across the element as a response to the application of said sequence; and
determining the impedance of the element from the measured voltage variations,
wherein said sequence is a non-binary sequence obtained by convolution of a pseudo-random binary sequence with coefficients of a finite impulse response filter.

8. The device of claim 7, wherein said circuit comprises a discharge branch intended to be connected in parallel with the element, this branch comprising a transistor capable of being controlled in an area of linear operation to apply to the element non-binary current variations.

9. The device of claim 7, wherein the transistor is controlled via an operational amplifier, and wherein a feedback loop connects said branch to an input terminal of the amplifier.

10. The device of claim 7, wherein said circuit comprises a power supply circuit capable of storing electric energy in a capacitor before an impedance measurement phase, to power the device during the measurement phase.

11. An assembly comprising:
an electric battery comprising at least one energy storage element; and
a device for managing the battery coupled to the battery, the management device comprising at least one device of claim 7, capable of measuring the impedance of the storage element.

12. The assembly of claim 11, wherein the battery comprises a plurality of storage elements, and wherein the management device comprises a plurality of impedance measurement devices respectively assigned to the different storage elements, the different impedance measurement devices being capable of applying different current variation sequences to the different storage elements.

13. The assembly of claim 12, wherein the management device is capable of identifying the different elements with the current variation sequence which is applied thereto during an impedance measurement.
